(19) United States
(12) Patent Application Publication
(10) Pub. No.: US 2026/0351168 A1
(43) Pub. Date: Nov. 5, 2026

(54) LIFETIME EVALUATION DEVICE OF DISPLAY PANEL, AND LIFETIME EVALUATION METHOD OF THE DISPLAY PANEL

(71) Applicant: Samsung Display Co., Ltd., Yongin-si (KR)

(72) Inventors: SAERON PARK, Yongin-si (KR); EUN-AH SUNG, Yongin-si (KR)

(21) Appl. No.: 19/441,634

(22) Filed: Jan. 6, 2026

(30) Foreign Application Priority Data
Apr. 16, 2025 (KR) 10-2025-0049647

(51) Int. Cl. G09G 3/3225

(52) U.S. Cl. CPC G09G 3/3225; G09G 2310/08; G09G 2320/0223; G09G 2320/048; G09G 2330/021; G09G 2360/16

(57) ABSTRACT

A lifetime evaluation device of a display panel includes: a display panel including a light-emitting element; a voltage outputter including a light-receiving element configured to receive a luminance of the light-emitting element and to generate an input current, and an RC circuit connected to the light-receiving element and configured to generate an output voltage; a voltage measurer configured to measure the output voltage; and a lifetime evaluation controller configured to evaluate a lifespan of the display panel based on the output voltage, wherein the RC circuit includes a variable light-receiving resistor and a light-receiving capacitor, and a resistance value of the variable light-receiving resistor is configured to change according to an on-duty of the light-emitting element.

### CROSS-REFERENCE TO RELATED APPLICATION

The present application claims priority to and the benefit of Korean Patent Application No. 10-2025-0049647, filed on Apr. 16, 2025, in the Korean Intellectual Property Office, the entire disclosure of which is incorporated herein by reference.

### BACKGROUND

### 1. Field

Aspects of some embodiments of the present disclosure relate to a lifetime evaluation device of a display panel, and a lifetime evaluation method of the display panel.

### 2. Description of the Related Art

A display device includes a display panel and a display panel driver. The display panel displays images, and the display panel driver drives the display panel. The display panel includes a pixel to display the images. The pixels include a light-emitting element, and the light-emitting elements emit a light, such that the display panel displays the images.

However, the light-emitting element may deteriorate over time with a use, a luminance of the light-emitting element may decrease, and a display quality may decrease. When the luminance of the light-emitting element decreases to a specific luminance compared to an initial luminance, the display quality may become unsuitable for a use, and the display panel may be evaluated to reach an end of a lifespan. Therefore, an evaluation for the lifespan of the display panel may be desirable to accurately predict the display quality.

The above information disclosed in this Background section is only for enhancement of understanding of the background and therefore the information discussed in this Background section does not necessarily constitute prior art.

### SUMMARY

Aspects of some embodiments of the present disclosure relate to a lifetime evaluation device of a display panel, and a lifetime evaluation method of the display panel. For example, aspects of some embodiments of the present disclosure relate to a lifetime evaluation device of a display panel, and a lifetime evaluation method of the display panel for evaluating a lifetime of a display panel.

Aspects of some embodiments of the present disclosure include a lifetime evaluation device of a display panel for relatively improving a reliability of a life evaluation.

Aspects of some embodiments of the present disclosure include a lifetime evaluation method of a display panel for driving the lifetime evaluation device of the display panel.

According to some embodiments of the present disclosure, a lifetime evaluation device of a display panel includes a display panel including a light-emitting element, a voltage outputter including a light-receiving element configured to receive a luminance of the light-emitting element and to generate an input current, and an RC circuit connected to the light-receiving element and configured to generate an output voltage, a voltage measurer configured to measure the output voltage, and a lifetime evaluation controller configured to evaluate a lifespan of the display panel based on the output voltage. According to some embodiments, the RC circuit includes a variable light-receiving resistor and a light-receiving capacitor, and a resistance value of the variable light-receiving resistor changes according to an on-duty of the light-emitting element.

According to some embodiments, the lifetime evaluation controller may be configured to calculate the luminance of the light-emitting element based on the output voltage. According to some embodiments, when the luminance of the light-emitting element is less than a luminance threshold value, the lifetime evaluation controller may be configured to evaluate the lifetime of the display panel is ended.

According to some embodiments, as the on-duty of the light-emitting element is small, the resistance value of the variable light-receiving resistor may be large.

According to some embodiments, the resistance value of the variable light-receiving resistor may change according to a driving frequency of the display panel.

According to some embodiments, as the driving frequency of the display panel is large, the resistance value of the variable light-receiving resistor may be large.

According to some embodiments, the voltage outputter may further include an amplifier configured to amplify the output voltage.

According to some embodiments, a measurement cycle of the output voltage may change according to the on-duty of the light-emitting element.

According to some embodiments, as the on-duty of the light-emitting element is small, the measurement cycle of the output voltage may be long.

According to some embodiments, the measurement cycle of the output voltage may change according to a driving frequency of the display panel.

According to some embodiments, as the driving frequency of the display panel is large, the measurement cycle of the output voltage may be long.

According to some embodiments, the voltage measurer may further include a fixed RC circuit including a fixed light-receiving resistor and a fixed light-receiving capacitor. According to some embodiments, the RC circuit and the fixed RC circuit may be selectively connected to the light-emitting element.

According to some embodiments, the display panel may include at least two display panels, and the lifetime evaluation controller may be configured to evaluate a lifetime of each of the display panels.

According to some embodiments of the present disclosure, in a lifetime evaluation method of a display panel the method includes: receiving a luminance of a light-emitting element included in a display panel to generate an input current using a voltage outputter, generating an output voltage based on the input current using an RC circuit included in the voltage outputter, measuring the output voltage, and evaluating a lifetime of the display panel based on the output voltage. According to some embodiments, the RC circuit includes a variable light-receiving resistor and a light-receiving capacitor, and a resistance value of the variable light-receiving resistor changes according to an on-duty of the light-emitting element.

According to some embodiments, the luminance of the light-emitting element may be calculated based on the output voltage. When the luminance of the light-emitting element is less than a luminance threshold value, the lifetime evaluation controller may be configured to evaluate the lifetime of the display panel is ended.

According to some embodiments, as the on-duty of the light-emitting element is small, the resistance value of the variable light-receiving resistor may be large.

According to some embodiments, the resistance value of the variable light-receiving resistor may change according to a driving frequency of the display panel.

According to some embodiments, as the driving frequency of the display panel is large, the resistance value of the variable light-receiving resistor may be large.

According to some embodiments, the voltage outputter may further include an amplifier configured to amplify the output voltage.

According to some embodiments, a measurement cycle of the output voltage may change according to the on-duty of the light-emitting element.

According to some embodiments, as the on-duty of the light-emitting element is small, the measurement cycle of the output voltage may be long.

According to the lifetime evaluation device and the lifetime evaluation method, a resistance value of the variable light-receiving resistor may change according to an on-duty and a driving frequency of the display panel such that a performance of the RC circuit as a low-pass filter is relatively improved and a reliability of a lifetime evaluation of the display panel may be relatively improved.

### BRIEF DESCRIPTION OF THE DRAWINGS

The above and other features of some embodiments of the present disclosure will become more apparent by describing in more detail aspects of some embodiments thereof with reference to the accompanying drawings, in which:

FIG. 1 is a block diagram showing a display device according to some embodiments of the present disclosure;

FIG. 2 is a circuit diagram showing an example of a pixel of FIG. 1;

FIG. 3 is a timing diagram showing an example of an operation of a pixel of FIG. 2;

FIG. 4 is a circuit diagram showing an example of an operation of a pixel of FIG. 2 in an initialization period of FIG. 3;

FIG. 5 is a circuit diagram showing an example of an operation of a pixel of FIG. 2 in a compensation period of FIG. 3;

FIG. 6 is a circuit diagram showing an example of an operation of a pixel of FIG. 2 in a data write period of FIG. 3;

FIG. 7 is a circuit diagram showing an example of an operation of a pixel PX of FIG. 2 in a light emission period of FIG. 3;

FIG. 8 is a block diagram showing a lifetime evaluation device according to some embodiments of the present disclosure;

FIG. 9 and FIG. 10 are perspective views showing a voltage outputter of FIG. 8;

FIG. 11 is a circuit diagram showing a light-emitting element included in a display panel of FIG. 1, and a light-receiving element and an RC circuit included in a voltage outputter of FIG. 9 and FIG. 10;

FIG. 12 is a graph showing a time-luminance graph generated by a lifetime evaluation controller of FIG. 8;

FIG. 13 is a diagram showing an electronic device including a display device of FIG. 1;

FIG. 14 is a diagram describing an example of a motion blur according to a driving frequency of a display panel of FIG. 1, and an on-duty in an electronic device of FIG. 13;

FIG. 15 is a conceptual diagram describing a motion blur according to a driving frequency of a display panel of FIG. 1;

FIG. 16 and FIG. 17 are conceptual diagrams describing an on-duty and an off-duty;

FIG. 18 is a conceptual diagram describing a motion blur according to an on-duty of FIG. 16 and FIG. 17;

FIG. 19 is a graph showing a noise according to an on-duty;

FIG. 20 is a graph showing an example of a method for increasing a reliability of a lifetime evaluation of a lifetime evaluation device of FIG. 8;

FIG. 21 and FIG. 22 are circuit diagrams showing examples of a method for increasing a reliability of a lifetime evaluation of a lifetime evaluation device of FIG. 8;

FIG. 23 is a block diagram showing an example of a method for increasing a reliability of a lifetime evaluation of a lifetime evaluation device of FIG. 8;

FIG. 24 is a block diagram showing an electronic device according to some embodiments of the present disclosure;

FIG. 25 is a diagram showing an example in which an electronic device of FIG. 24 is implemented as a VR device;

FIG. 26 is a block diagram showing an electronic device according to some embodiments of the present disclosure; and

FIG. 27 is schematic diagrams showing electronic devices of FIG. 26.

### DETAILED DESCRIPTION

Hereinafter, aspects of some embodiments of the present disclosure will be described in more detail with reference to the accompanying drawings.

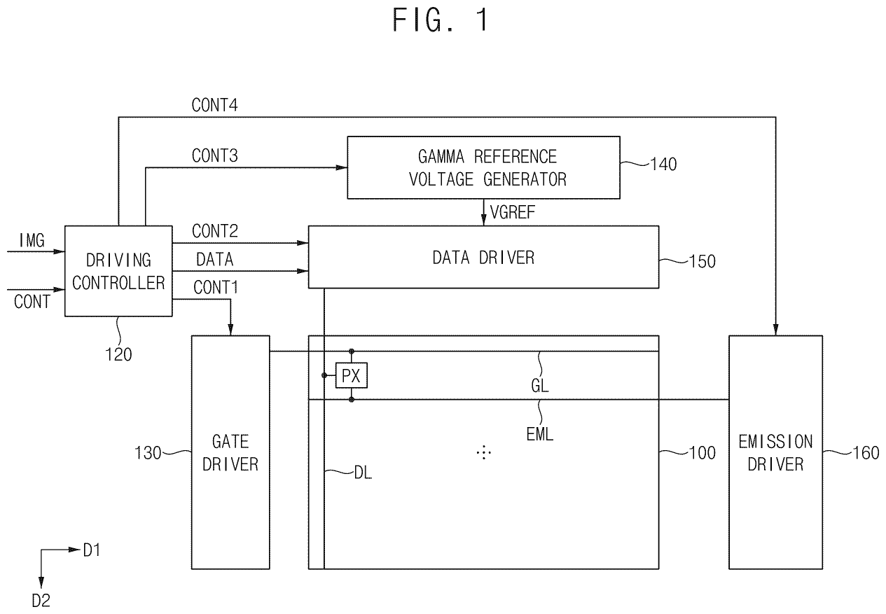

FIG. 1 is a block diagram showing aspects of a display device according to some embodiments of the present disclosure.

Referring to FIG. 1, a display device may include a display panel 100 and a display panel driver. The display panel driver may include a driving controller 120, a gate driver 130, a gamma reference voltage generator 140, and a data driver 150. The display panel driver may further include an emission driver 160.

For example, the driving controller 120 and the data driver 150 may be formed integrally (e.g., as a single component or chip). For example, the driving controller 120, the gamma reference voltage generator 140, and the data driver 150 may be formed integrally (e.g., as a single component or chip). For example, the driving controller 120, the gate driver 130, the gamma reference voltage generator 140, and the data driver 150 may be formed integrally (e.g., as a single component or chip). For example, the driving controller 120, the gate driver 130, the gamma reference voltage generator 140, the data driver 150, and the emission driver 160 may be formed integrally (e.g., as a single component or chip). Meanwhile, a driving module in which at least the driving controller 120 and the data driver 150 are formed integrally may be named a timing controller embedded data driver (TED).

The display panel 100 may include a display area for displaying images and a peripheral area located adjacent to the display area.

For example, the display panel 100 may be an organic light-emitting diode display panel including an organic light-emitting diode. For example, the display panel 100 may be a quantum-dot organic light-emitting diode display panel including an organic light-emitting diode and a quantum-dot color filter. For example, the display panel 100 may be a quantum-dot nano light-emitting diode display panel including a nano light-emitting diode and a quantum-dot color filter.

The display panel 100 may include gate lines GL, data lines DL, emission lines EML, and pixels PX electrically connected to the gate lines GL, the data lines DL, and the emission lines EML, respectively. The gate lines GL may extend in a first direction D1, the data lines DL may extend in a second direction D2 crossing the first direction D1, and the emission lines EML may extend in the first direction D1.

The driving controller 120 may receive input image data IMG and an input control signal CONT from an external device. For example, the input image data IMG may include red image data, green image data and blue image data. The input image data IMG may include white image data. The input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 120 may generate a first control signal CONT1, a second control signal CONT2, a third control signal CONT3, a fourth control signal CONT4, and a data signal DATA based on the input image data IMG and the input control signal CONT.

The driving controller 120 may generate the first control signal CONT1 for controlling an operation of the gate driver 130 based on the input control signal CONT, and output the first control signal CONT1 to the gate driver 130. The first control signal CONT1 may include a vertical start signal and a gate clock signal.

The driving controller 120 may generate the second control signal CONT2 for controlling an operation of the data driver 150 based on the input control signal CONT, and output the second control signal CONT2 to the data driver 150. The second control signal CONT2 may include a horizontal start signal and a load signal.

The driving controller 120 may generate the data signal DATA based on the input image data IMG. The driving controller 120 may output the data signal DATA to the data driver 150.

The driving controller 120 may generate the third control signal CONT3 for controlling an operation of the gamma reference voltage generator 140 based on the input control signal CONT, and output the third control signal CONT3 to the gamma reference voltage generator 140.

The driving controller 120 may generate the fourth control signal CONT4 for controlling an operation of the emission driver 160 based on the input control signal CONT, and output the fourth control signal CONT4 to the emission driver 160.

The gate driver 130 may generate gate signals for driving the gate lines GL in response to the first control signal CONT1 received from the driving controller 120. The gate driver 130 may output the gate signals to the gate lines GL.

According to some embodiments, the gate driver 130 may be integrated into or positioned at the peripheral area of the display panel 100. According to some embodiments, the gate driver 130 may be mounted into (or positioned at) the peripheral area of the display panel 100.

The gamma reference voltage generator 140 may generate a gamma reference voltage VGREF based on the third control signal CONT3 received from the driving controller 120. The gamma reference voltage generator 140 may output the gamma reference voltage VGREF to the data driver 150. The gamma reference voltage VGREF may have a value corresponding to each data signal DATA.

For example, the gamma reference voltage generator 140 may be located within the driving controller 120 or may be located within the data driver 150.

The data driver 150 may receive the second control signal CONT2 and the data signal DATA from the driving controller 120, and may receive the gamma reference voltage VGREF from the gamma reference voltage generator 140. The data driver 150 may convert the data signal DATA into an analog data voltage using the gamma reference voltage VGREF. The data driver 150 may output the data voltage to the data line DL.

According to some embodiments, the data driver 150 may be integrated into the peripheral area of the display panel 100. According to some embodiments, the data driver 150 may be mounted in (or positioned at) the peripheral area of the display panel 100.

The emission driver 160 may generate emission signals for driving the emission lines EML in response to the fourth control signal CONT4 received from the driving controller 120. The emission driver 160 may output the emission signals to the emission lines EML.

According to some embodiments, the emission driver 160 may be integrated in the peripheral area of the display panel 100. According to some embodiments, the emission driver 160 may be mounted in the peripheral area of the display panel 100.

In FIG. 1, for a convenience of an explanation, the gate driver 130 may be located on a first side of the display panel 100 and the emission driver 160 may be located on a second side of the display panel 100. Although shown, embodiments according to the present disclosure are not limited thereto. For example, both the gate driver 130 and the emission driver 160 may be located on the first side of the display panel 100. For example, both the gate driver 130 and the emission driver 160 may be located on both sides of the display panel 100. For example, the gate driver 130 and the emission driver 160 may be formed integrally (e.g., as a single component or chip).

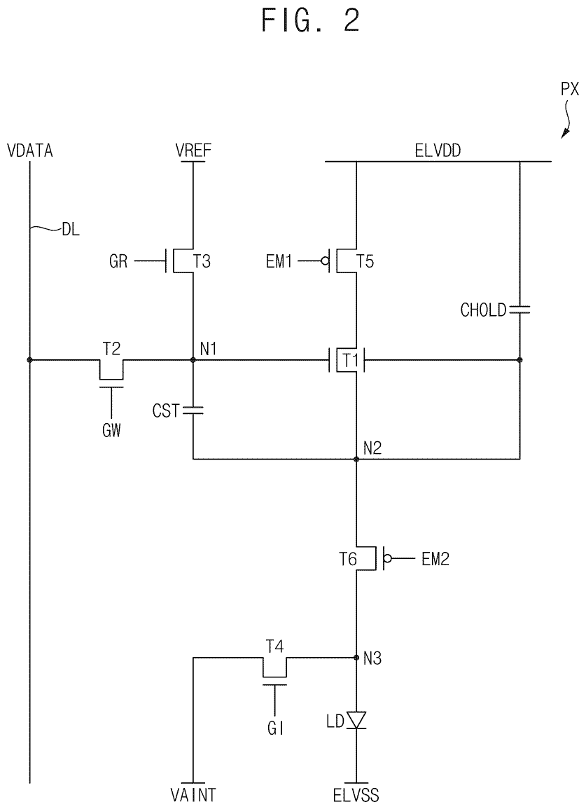

FIG. 2 is a circuit diagram showing an example of a pixel PX of FIG. 1. Although FIG. 2 illustrates various components in a pixel according to some embodiments, embodiments according to the present disclosure are not limited thereto, and according to various embodiments, the pixel may include additional components, or fewer components, without departing from the spirit and scope of embodiments according to the present disclosure.

Referring to FIGS. 1 and 2, the display panel 100 may include the pixel PX. The pixel PX may include a first transistor T1, a second transistor T2, a third transistor T3, a fourth transistor T4, a fifth transistor T5, a sixth transistor T6, a storage capacitor CST, a hold capacitor CHOLD, and a light-emitting element LD. However, the pixel PX included in the display panel 100 of FIG. 1 is not limited thereto.

According to some embodiments, the fifth transistor T5 and the sixth transistor T6 may be PMOS transistors, and the first transistor T1, the second transistor T2, the third transistor T3, and the fourth transistor T4 may be NMOS transistors.

The PMOS transistor may be turned on when a gate-source voltage of the PMOS transistor is less than or equal to a threshold voltage (e.g., a negative value) of the PMOS transistor. On the other hand, the PMOS transistor may be turned off when the gate-source voltage of the PMOS transistor is greater than the threshold voltage of the PMOS transistor. For example, when a gate signal having a low level is applied to a gate electrode of the PMOS transistor, the PMOS transistor may be turned on. For example, when a gate signal having a high level is applied to the gate electrode of the PMOS transistor, the PMOS transistor may be turned off. Therefore, a turn-on level of the PMOS transistor may be the low level, and a turn-off level of the PMOS transistor may be the high level.

The NMOS transistor may be turned on when a gate-source voltage of the NMOS transistor is greater than or equal to a threshold voltage (e.g., a positive value) of the NMOS transistor. On the other hand, the NMOS transistor may be turned off when the gate-source voltage of the NMOS transistor is less than the threshold voltage of the NMOS transistor. For example, when a gate signal having the high level is applied to the gate electrode of the NMOS transistor, the PMOS transistor may be turned on. For example, when a gate signal having the low level is applied to the gate electrode of the NMOS transistor, the NMOS transistor may be turned off. Therefore, a turn-on level of the NMOS transistor may be the high level, and a turn-off level of the NMOS transistor may be the low level.

The first transistor T1 may include a gate electrode connected to a first node N1, a first electrode, a second electrode connected to a second node N2, and a back gate electrode connected to the second node N2. The first transistor T1 may be turned on based on a voltage of the first node N1 and a voltage of the second node N2 to generate a driving current. For example, the first transistor T1 may generate the driving current based on a difference value between the voltage of the first node N1 and the voltage of the second node N2. Therefore, as the difference value between the voltage of the first node N1 and the voltage of the second node N2 is large, a magnitude of the driving current may be large. For example, the first transistor T1 may be referred to as a driving transistor.

The second transistor T2 may include a gate electrode receiving a data write gate signal GW, a first electrode connected to a data line DL transmitting a data voltage VDATA, and a second electrode connected to the first node N1. The second transistor T2 may be turned on in response to a data write gate signal GW having the high level to provide the data voltage VDATA to the first node N1. For example, the second transistor T2 may be referred to as a data write transistor.

The third transistor T3 may include a gate electrode receiving a reset gate signal GR, a first electrode receiving a reference voltage VREF, and a second electrode connected to the first node N1. The third transistor T3 may be turned on in response to a reset gate signal GR having the high level to provide the reference voltage VREF to the first node N1. For example, the third transistor T3 may be referred to as a reset transistor.

The fourth transistor T4 may include a gate electrode receiving an initialization gate signal GI, a first electrode receiving an anode initialization voltage VAINT, and a second electrode connected to a third node N3. The fourth transistor T4 may be turned on in response to an initialization gate signal GI having the high level to provide the anode initialization voltage VAINT to the third node N3. For example, the fourth transistor T4 may be referred to as an anode initialization transistor.

The fifth transistor T5 may include a gate electrode receiving a first emission signal EM1, a first electrode receiving a first power supply voltage ELVDD, and a second electrode connected to the first electrode of the first transistor T1. The sixth transistor T6 may include a gate electrode receiving a second emission signal EM2, a first electrode connected to the second node N2, and a second electrode connected to a third node N3. The fifth transistor T5 may control the driving current to be applied to the light-emitting element LD in response to the first emission signal EM1 to control a light emission of the light-emitting element LD. The sixth transistor T6 may control the driving current to be applied to the light-emitting element LD in response to the second emission signal EM2 to control the light emission of the light-emitting element LD. For example, the fifth transistor T5 may be referred to as a first light emission control transistor, and the sixth transistor T6 may be referred to as a second light emission control transistor.

The storage capacitor CST may include a first electrode connected to the first node N1 and a second electrode connected to the second node N2. The storage capacitor CST may store the data voltage VDATA.

The hold capacitor CHOLD may include a first electrode receiving the first power supply voltage ELVDD and a second electrode connected to the second node N2. The hold capacitor CHOLD may hold the voltage of the second node N2.

The light-emitting element LD may include an anode electrode connected to the third node N3 and a cathode electrode receiving a second power supply voltage ELVSS. The light-emitting element LD may emit a light based on the driving current. As the magnitude of the driving current is large, a luminance corresponding to a light emission intensity of the light-emitting element LD may be large.

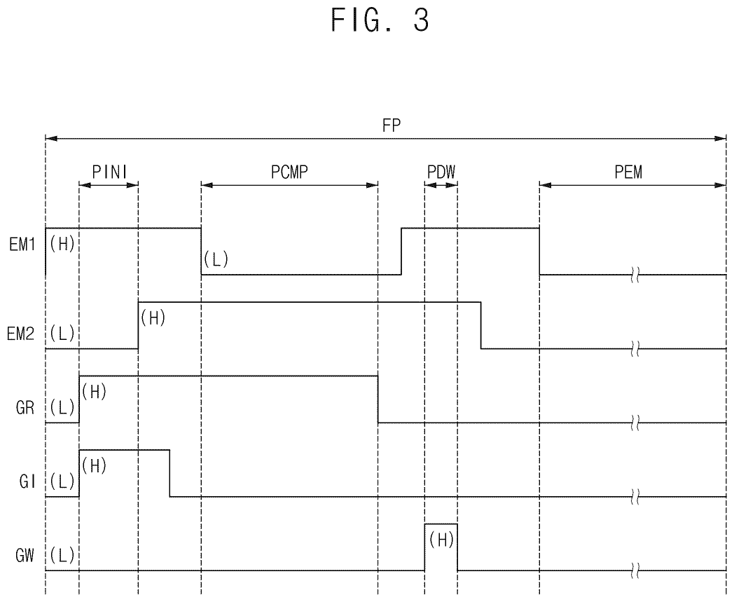

FIG. 3 is a timing diagram showing aspects of an operation of a pixel PX of FIG. 2.

Referring to FIGS. 1 to 3, the pixel PX may operate in frame units. A frame period FP of the pixel PX may include an initialization period PINI, a compensation period PCMP, a data write period PDW, and an light emission period PEM.

In the initialization period PINI, the first emission signal EM1 may have the high level H, the second emission signal EM2 may have the low level L, the reset gate signal GR may have the high level H, the initialization gate signal GI may have the high level H, and the data writing gate signal GW may have the low level L.

In the compensation period PCMP, the first emission signal EM1 may have the low level L, the second emission signal EM2 may have the high level H, the reset gate signal GR may have the high level H, the initialization gate signal GI may have the low level L, and the data write gate signal GW may have the low level L.

In the data write period PDW, the first emission signal EM1 may have the high level H, the second emission signal EM2 may have the high level H, the reset gate signal GR may have the low level L, the initialization gate signal GI may have the low level L, and the data write gate signal GW may have the high level H.

In the light emission period PEM, the first emission signal EM1 may have the low level L, the second emission signal EM2 may have the low level L, the reset gate signal GR may have the low level L, the initialization gate signal GI may have the low level L, and the data write gate signal GW may have the low level L.

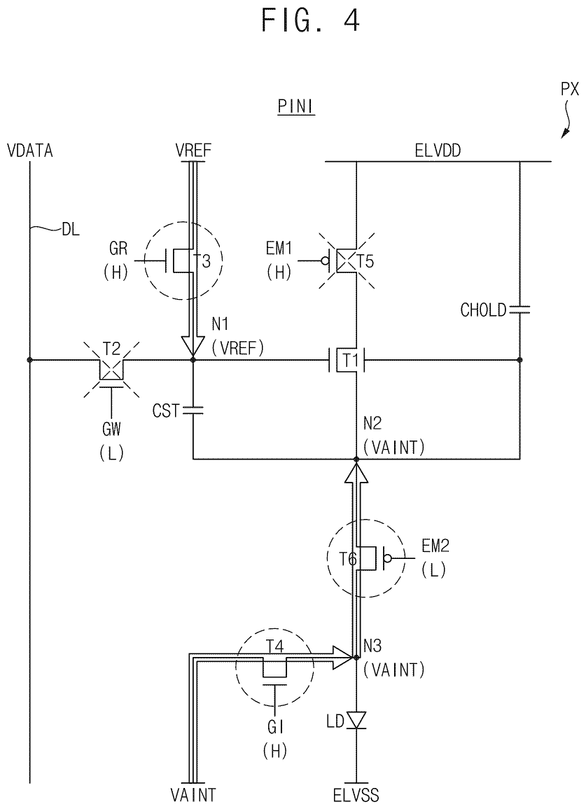

FIG. 4 is a circuit diagram showing an example of an operation of a pixel PX of FIG. 2 in an initialization period PINI of FIG. 3.

Referring to FIGS. 1 to 4, in the initialization period PINI, the second transistor T2 may be turned off in response to the data write gate signal GW having the low level L, the third transistor T3 may be turned on in response to the reset gate signal GR having the high level H, the fourth transistor T4 may be turned on in response to the initialization gate signal GI having the high level H, the fifth transistor T5 may be turned off in response to the first emission signal EM1 having the high level H, and the sixth transistor T6 may be turned on in response to the second emission signal EM2 having the low level L.

The fourth transistor T4 may be turned on to provide the anode initialization voltage VAINT to the third node N3. Therefore, a voltage of the third node N3 may become the anode initialization voltage VAINT. Because the anode electrode of the light-emitting element LD is connected to the third node N3, a voltage of the anode electrode of the light-emitting element LD may be initialized to the anode initialization voltage VAINT.

The sixth transistor T6 may be turned on to provide the voltage of the third node N3 to the second node N2. Therefore, the voltage of the second node N2 may become the anode initialization voltage VAINT. Because the second electrode of the first transistor T1 is connected to the second node N2, a voltage of the second electrode of the first transistor T1 may be initialized to the anode initialization voltage VAINT.

The third transistor T3 may be turned on to provide the reference voltage VREF to the first node N1. Therefore, the voltage of the first node N1 may become the reference voltage VREF. Because the gate electrode of the first transistor T1 is connected to the first node N1, a voltage of the gate electrode of the first transistor T1 may be initialized to the reference voltage VREF.

In addition, because the first electrode of the storage capacitor CST is connected to the first node N1, a voltage of the first electrode of the storage capacitor CST may be initialized to the reference voltage VREF. Because the second electrode of the storage capacitor CST is connected to the second node N2, a voltage of the second electrode of the storage capacitor CST may be initialized to the anode initialization voltage VAINT.

As such, in the initialization period PINI, initialization operations may be performed for the voltage of the gate electrode of the first transistor T1, the voltage of the second electrode of the first transistor T1, the voltage of the first electrode of the storage capacitor CST, the voltage of the second electrode of the storage capacitor CST, and the voltage of the anode electrode of the light-emitting element LD.

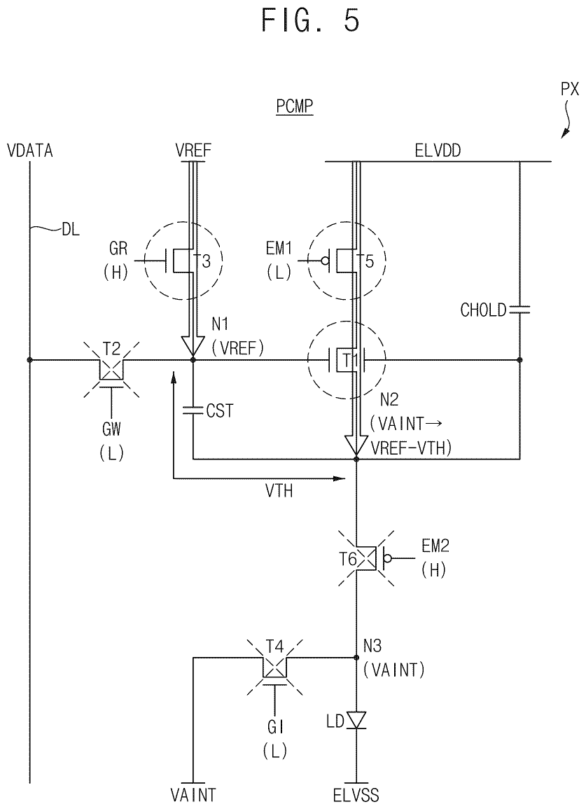

FIG. 5 is a circuit diagram showing an example of an operation of a pixel PX of FIG. 2 in a compensation period PCMP of FIG. 3.

Referring to FIGS. 1 to 5, in the compensation period PCMP, the second transistor T2 may be turned off in response to the data write gate signal GW having the low level L, the third transistor T3 may be turned on in response to the reset gate signal GR having the high level H, the fourth transistor T4 may be turned off in response to the initialization gate signal GI having the low level L, the fifth transistor T5 may be turned on in response to the first emission signal EM1 having the low level L, and the sixth transistor T6 may be turned off in response to the second emission signal EM2 having the high level H.

The third transistor T3 may be turned on to provide the reference voltage VREF to the first node N1. Therefore, the voltage of the first node N1 may become the reference voltage VREF. Because the gate electrode of the first transistor T1 is connected to the first node N1, the voltage of the gate electrode of the first transistor T1 may be initialized to the reference voltage VREF.

The fifth transistor T5 may be turned on to provide the first power supply voltage ELVDD to the first electrode of the first transistor T1. Therefore, a voltage of the first electrode of the first transistor T1 may become the first power supply voltage ELVDD.

The voltage of the gate electrode of the first transistor T1 is the reference voltage VREF, and the voltage of the second electrode (i.e., a source electrode) of the first transistor T1 is the anode initialization voltage VAINT. In this case, the gate-source voltage (i.e., “VREF-VAINT”) of the first transistor T1 may be greater than or equal to a threshold voltage VTH of the first transistor T1. Therefore, the first transistor T1 may be turned on. The first transistor T1 may be turned on until the voltage of the second node N2 becomes a voltage (i.e., “VREF-VTH”) obtained by subtracting the threshold voltage VTH of the first transistor T1 from the reference voltage VREF.

Because the voltage of the first node N1 is the reference voltage VREF and the voltage of the second node N2 is the voltage (i.e., “VREF-VTH”) obtained by subtracting the threshold voltage VTH of the first transistor T1 from the reference voltage VREF, the storage capacitor CST may store the threshold voltage VTH of the first transistor T1 between the first electrode of the storage capacitor CST and the second electrode of the storage capacitor CST.

As such, in the compensation period PCMP, because the storage capacitor CST stores the threshold voltage VTH of the first transistor T1, a compensation operation for the threshold voltage VTH of the first transistor T1 may be performed.

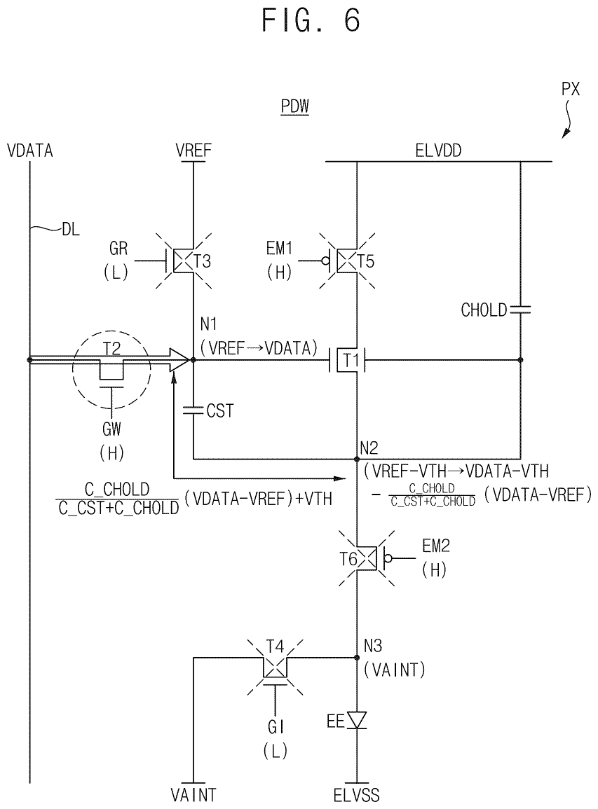

FIG. 6 is a circuit diagram showing an example of an operation of a pixel PX of FIG. 2 in a data write period PDW of FIG. 3.

Referring to FIGS. 1 to 6, in the data write period PDW, the second transistor T2 may be turned on in response to the data writing gate signal GW having the high level H, the third transistor T3 may be turned off in response to the reset gate signal GR having the low level L, the fourth transistor T4 may be turned off in response to the initialization gate signal GI having the low level L, the fifth transistor T5 may be turned off in response to the first emission signal EM1 having the high level H, and the sixth transistor T6 may be turned off in response to the second emission signal EM2 having the high level H.

The second transistor T2 may be turned on to provide the data voltage VDATA transmitted through the data line DL to the first node N1. Therefore, the voltage of the first node N1 may change from the reference voltage VREF to the data voltage VDATA by a difference value (i.e., “VDATA-VREF”) between the data voltage VDATA and the reference voltage VREF.

Because the storage capacitor CST and the hold capacitor CHOLD are connected in series, when the voltage of the first node N1 changes by the difference value (i.e., “VDATA-VREF”) between the data voltage VDATA and the reference voltage VREF, the voltage of the second node N2 may change by “C_CHOLD/(C_CST+C_CHOLD)×(VDATA−VREF)”. (Here, C_CHOLD is a capacitance of the hold capacitor CHOLD, and C_CST is a capacitance of the storage capacitor CST.) Therefore, the voltage of the second node N2 may be changed to “VDATA−VTH−C_CHOLD/(C_CST+C_CHOLD)×(VDATA−VREF)”.

Because the voltage of the first node N1 is the data voltage VDATA and the voltage of the second node N2 is “VDATA−VTH−C_CHOLD/(C_CST+C_CHOLD)×(VDATA−VREF)”, the storage capacitor CST may store “C_CHOLD/(C_CST+C_CHOLD)×(VDATA−VREF)+VTH” between the first electrode of the storage capacitor CST and the second electrode of the storage capacitor CST. That is, the storage capacitor CST may store a component of the data voltage VDATA.

As such, in the data write period PDW, a data write operation for the pixel PX may be performed.

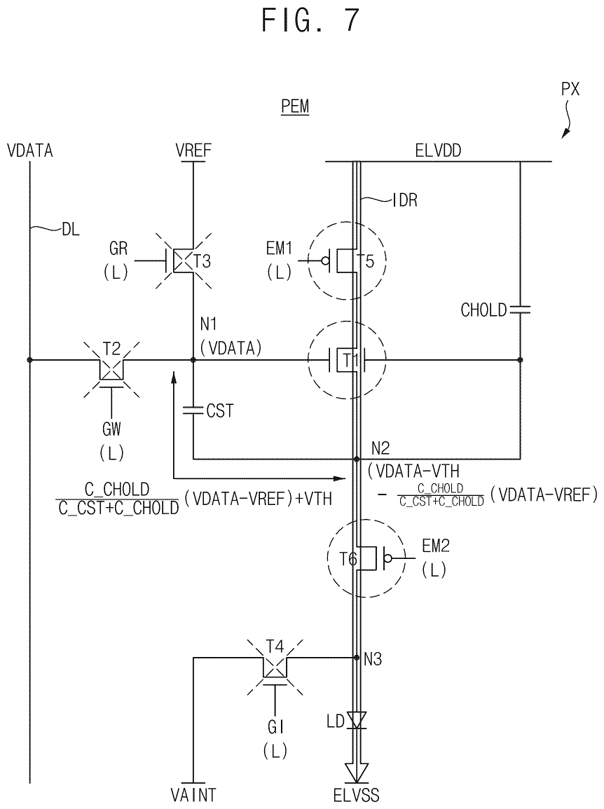

FIG. 7 is a circuit diagram showing an example of an operation of a pixel PX of FIG. 2 in a light emission period PEM of FIG. 3.

Referring to FIGS. 1 to 7, in the light emission period PEM, the second transistor T2 may be turned off in response to the data write gate signal GW having the low level L, the third transistor T3 may be turned off in response to the reset gate signal GR having the low level L, the fourth transistor T4 may be turned off in response to the initialization gate signal GI having the low level L, the fifth transistor T5 may be turned on in response to the first emission signal EM1 having the low level L, and the sixth transistor T6 may be turned on in response to the second emission signal EM2 having the low level L.

The first transistor T1 may be turned on based on the voltage of the first node N1 and the voltage of the second node N2 to generate the driving current IDR. Specifically, the first transistor T1 may generate the driving current IDR based on the gate-source voltage (i.e., “C_CHOLD/(C_CST+C_CHOLD)×(VDATA−VREF)+VTH”) of the first transistor T1. Because the gate-source voltage (i.e., “C_CHOLD/(C_CST+C_CHOLD)×(VDATA−VREF)+VTH”) of the first transistor T1 includes the component of the data voltage VDATA, the magnitude of the driving current IDR may vary according to the data voltage VDATA.

Because not only the first transistor T1, but also the fifth transistor T5 and the sixth transistor T6 are turned on, a transmission line of the driving current IDR may be formed between a line transmitting the first power supply voltage ELVDD and a line transmitting the second power supply voltage ELVSS.

Accordingly, the driving current IDR may be transmitted to the light-emitting element LD along the transmission line of the driving current IDR. The light-emitting element LD may emit the light based on the driving current IDR. As the magnitude of the driving current IDR is large, the luminance corresponding to the light emission intensity of the light-emitting element LD may be large.

As such, a light emission operation for the light-emitting element LD may be performed in the light emission period PEM.

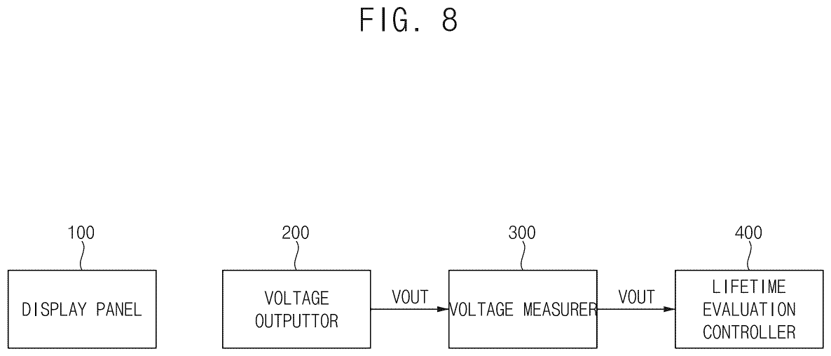

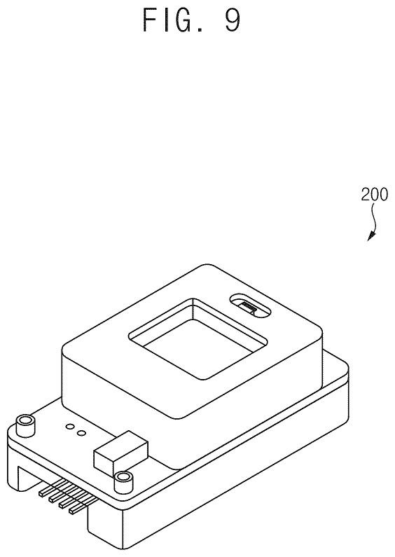

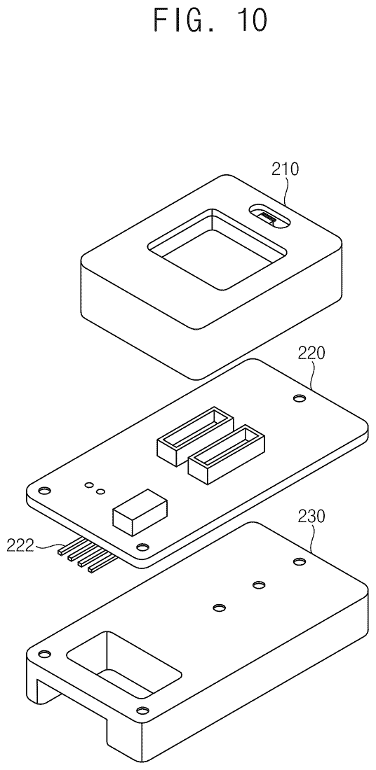

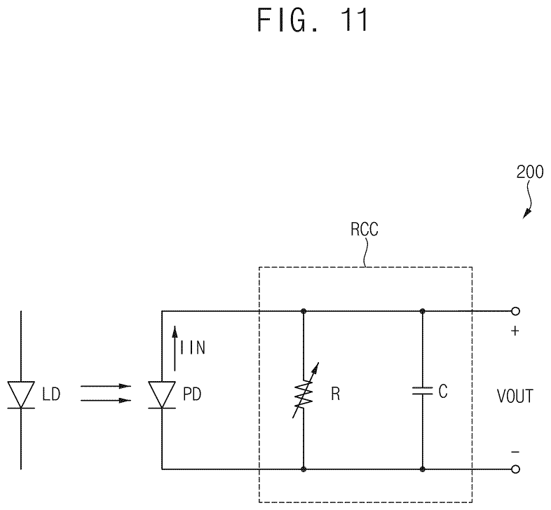

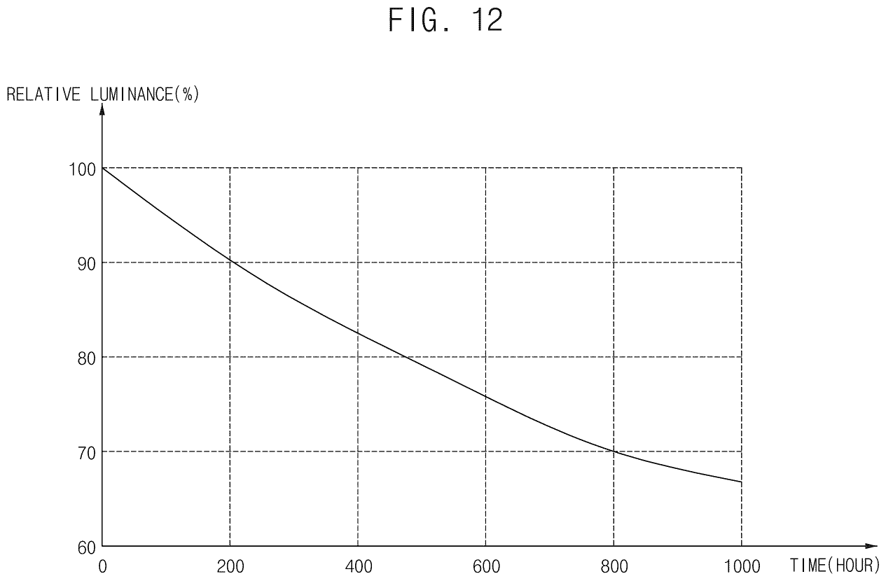

FIG. 8 is a block diagram showing a lifetime evaluation device according to some embodiments of the present disclosure. FIG. 9 and FIG. 10 are perspective views showing a voltage outputter (or voltage output component or voltage output circuit) 200 of FIG. 8. FIG. 11 is a circuit diagram showing a light-emitting element LD included in a display panel 100 of FIG. 1, and a light-receiving element PD and an RC circuit RCC included in a voltage outputter 200 of FIG. 9 and FIG. 10. FIG. 12 is a graph showing a time-luminance graph generated by a lifetime evaluation controller 400 of FIG. 8.

Referring to FIGS. 1 to 12, a lifetime evaluation device may evaluate the life of the display panel 100. The lifetime evaluation device may include the display panel 100, a voltage outputter 200, a voltage measurer 300, and a lifetime evaluation controller 400.

The voltage outputter 200 may generate and output an output voltage VOUT. The voltage outputter 200 may include a sensing unit 210, a PCB circuit unit 220, and a base unit 230.

The sensing unit 210 may be spaced apart from and overlap the display panel 100. The sensing unit 210 may include a light-receiving element PD. For example, the light-receiving element PD may be a photodiode. The light-receiving element PD may receive the light of the light-emitting element LD of the display panel 100 to generate an input current IIN. As the luminance of the light-emitting element LD is large, a magnitude of the input current IIN may be large.

The PCB circuit unit 220 may be connected to the sensing unit 210 and may include an RC circuit RCC. The RC circuit RCC is connected to the light-receiving element PD and may generate the output voltage VOUT based on the input current IIN. The PCB circuit unit 220 may output the output voltage VOUT through a PCB connector 222. For example, the PCB circuit unit 220 may be a PCB (Printed Circuit Board).

The base unit 230 may stably support the PCB circuit unit 220. The base unit 230 may have various shapes such that the PCB circuit unit 220 may be stably supported.

As shown in FIG. 11, the light-receiving element PD may be connected to the RC circuit RCC. The RC circuit RCC may include a variable light-receiving resistor R and a light-receiving capacitor C. The light-receiving element PD may be connected in parallel with the variable light-receiving resistor R and the light-receiving capacitor C.

The light-receiving element PD may receive the light of the light-emitting element LD to generate the input current IIN, and the RC circuit RCC may generate a output voltage VOUT based on the input current IIN. In the t (time)-domain, the output voltage VOUT for the input current IIN may be expressed as in [Mathematical Formula 1].

$$IIN ( t ) = \frac{VOUT ( t )}{R} + C \times \frac{dVOUT ( t )}{d t} \qquad Mathematical Formula 1$$

Here, R is a resistance value of the variable light-emitting resistor R, and C is a capacitance of the photodetector capacitor C.

[Mathematical Formula 1] may be expressed in the s (frequency)-domain based on Laplace transform as [Mathematical Formula 2].

$$\frac{VOUT ( s )}{IIN ( s )} = \frac{R}{1 + s \times C \times R} \qquad Mathematical Formula 2$$

That is, a time constant is R×C, and an amplitude is R. The time constant represents a response time of the output voltage VOUT for the input current IIN.

As shown in [Mathematical Formula 2], the RC circuit RCC may operate as a low-pass filter.

As shown in FIG. 12, as described above, as the luminance of the light-emitting element LD is large, the magnitude of the input current IIN may be large. As the magnitude of the input current IIN is large, a magnitude of the output voltage VOUT may be large.

The voltage measurer (or voltage measuring component or voltage measuring circuit) 300 may measure the output voltage VOUT. The voltage measurer 300 may provide the measured output voltage VOUT to the lifetime evaluation controller 400.

The lifetime evaluation controller 400 may evaluate the lifetime of the display panel 100 based on the output voltage VOUT. As the luminance of the light-emitting element LD is large, a magnitude of the output voltage VOUT may be large. Therefore, the lifetime evaluation controller 400 may calculate the luminance of the light-emitting element LD based on the output voltage VOUT and generate a time-luminance graph, as shown in FIG. 12.

The light-emitting element LD may deteriorate with a use. Therefore, the luminance of the display panel 100 may decrease over time. For example, the time-luminance graph may be expressed as a relative luminance over time. The relative luminance may be a ratio of a current luminance to an initial luminance. For example, when the time is 0 hour, the relative luminance may be 100%. For example, when the time is 200 hour, the relative luminance may be 90%. For example, when the time is 800 hour, the relative luminance may be 70%. When the relative luminance is less than a luminance threshold, the lifetime evaluation controller 400 may evaluate that the lifetime of the display panel 100 is ended.

According to some embodiments, the display panel 100 may include at least two display panels. In this case, the lifetime evaluation controller 400 may evaluate the lifetime of each of the display panels 100.

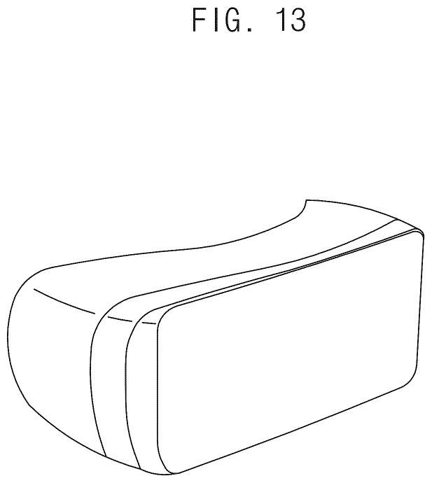

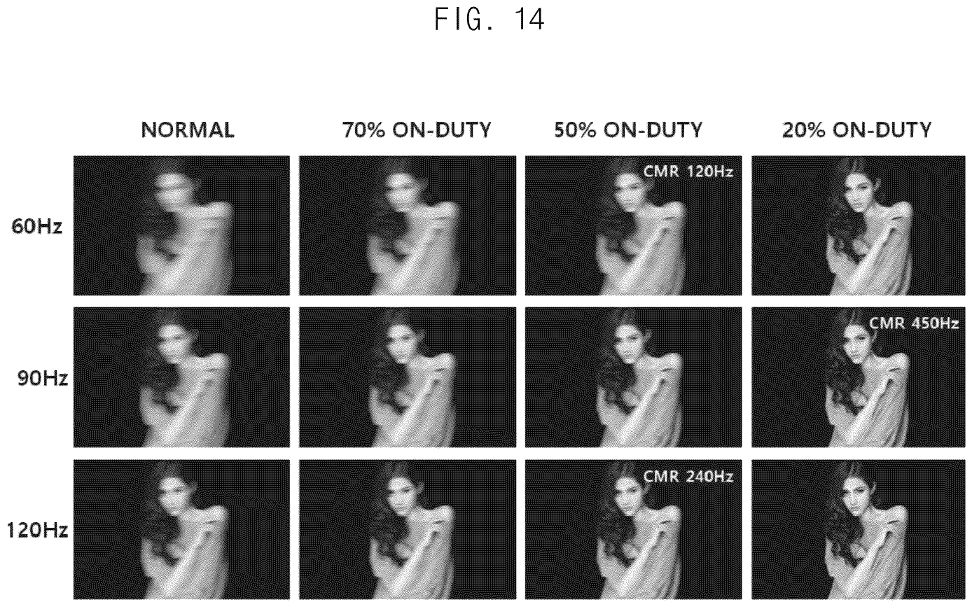

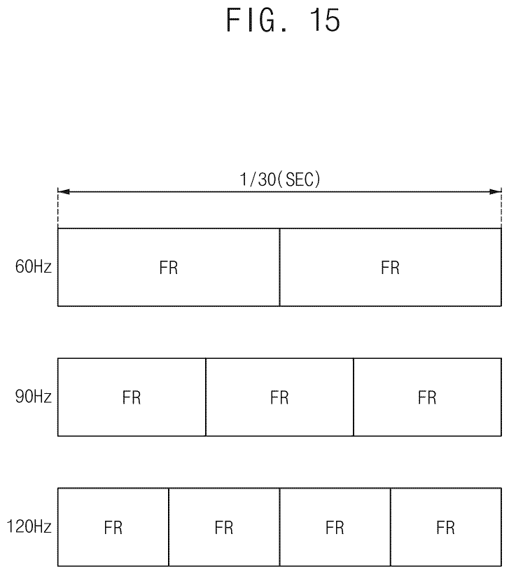

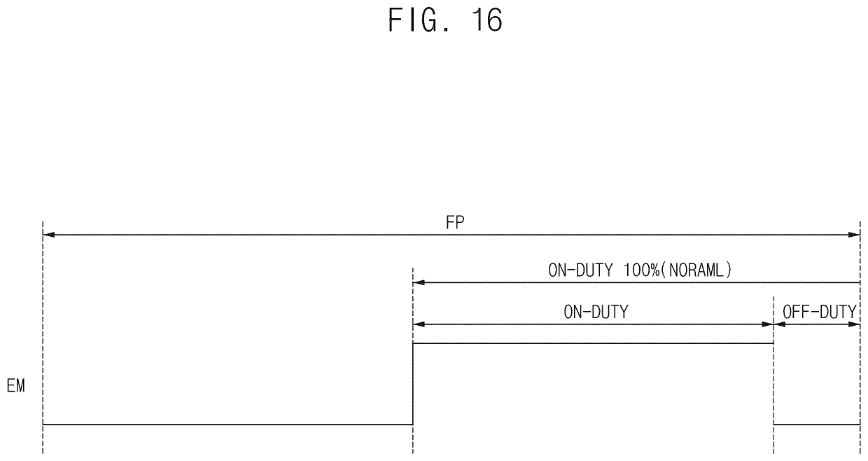

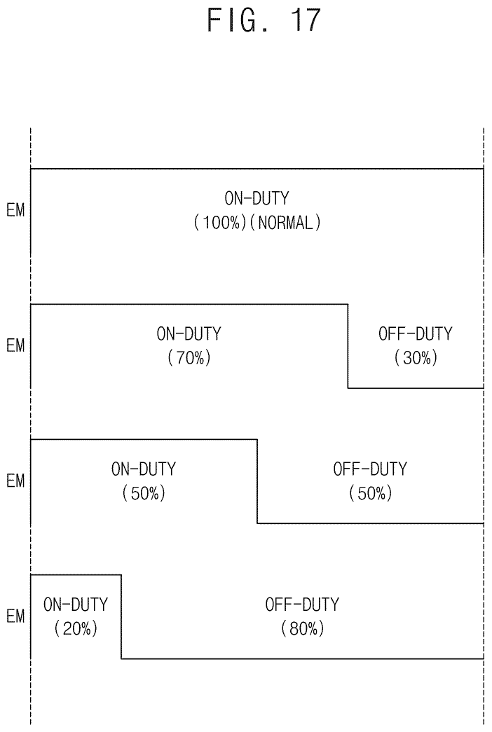

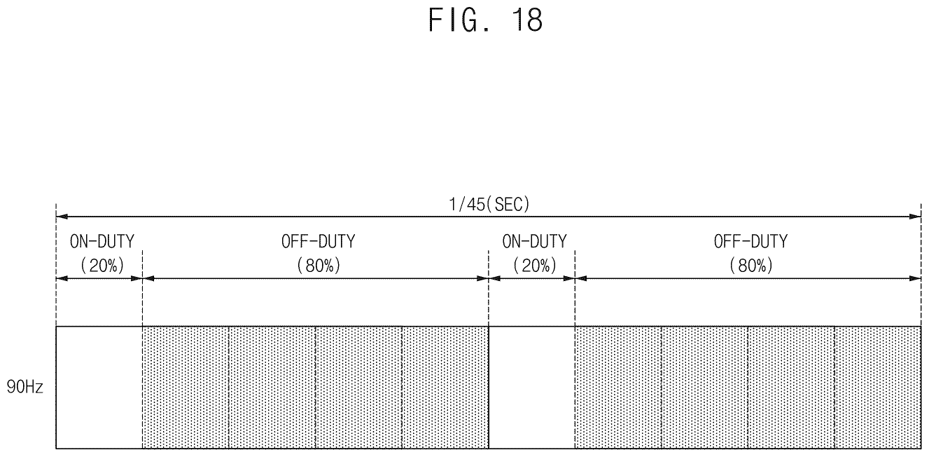

FIG. 13 is a diagram showing an electronic device including a display device of FIG. 1. FIG. 14 is a diagram describing an example of a motion blur according to a driving frequency of a display panel 100 of FIG. 1, and an on-duty in an electronic device of FIG. 13. FIG. 15 is a conceptual diagram describing a motion blur according to a driving frequency of a display panel 100 of FIG. 1. FIG. 16 and FIG. 17 are conceptual diagrams describing an on-duty and an off-duty. FIG. 18 is a conceptual diagram describing a motion blur according to an on-duty of FIG. 16 and FIG. 17.

Referring to FIGS. 1 to 18, a display device which provide virtual reality (VR) or augmented reality (AR) have recently been highlighted. For example, an electronic device including the display device may be implemented as a VR device.

Unlike a smartphone, a tablet PC, a laptop, a television, and a desktop monitor, the VR device may have a very short viewing distance. When the viewing distance is very short, a low area and high PPI (Pixels Per Inch) may be required for the display panel 100 to produce a clearer and more natural image.

In addition, when the viewing distance is very short, the user may easily experience a motion sickness. For example, the user may easily experience the motion sickness due to a motion blur (i.e., an afterimage) occurring in moving images (e.g., video images).

The motion blur may vary according to a driving frequency and an on-duty of the display panel 100.

The motion blur may vary according to the driving frequency of the display panel 100. For example, when the driving frequency of the display panel 100 is 60 Hz, a frame cycle may be 1/60 second. Therefore, two frames FR may exist during 1/30 second. For example, when the driving frequency of the display panel 100 is 90 Hz, the frame cycle may be 1/90 second. Therefore, three frames FR may exist in 1/30 second. For example, when the driving frequency of the display panel 100 is 120 Hz, the frame cycle may be 1/120 second. Therefore, four frames FR may exist in 1/30 second. In summary, as the driving frequency of the display panel 100 is small, the image may slowly change.

As the image slowly changes, the larger the size of the afterimage may be. Therefore, the lower the driving frequency of the display panel 100, the greater the motion blur may be. For example, motion blur at 60 Hz may be greater than motion blur at 90 Hz. For example, motion blur at 90 Hz may be greater than motion blur at 120 Hz.

The motion blur may vary according to the on-duty. The on-duty may be the ratio of the light emission period PEM to an light-emitting possible period. As described in FIG. 3, the light-emitting operation EM for the light-emitting element LD may be performed in the light emission period PEM. When a normal operation is performed for the light-emitting element LD, the on-duty may be 100%. (Here, when the normal operation is performed for the light-emitting element LD, the light emission period PEM may be the light-emitting possible period.) When the on-duty is less than 100%, the frame period FP may include an off-duty. The off-duty may be a ratio of a black period to the light-emitting possible period.

As the on-duty is small, the user's a visual system may interpolate and perceive the image during the off-duty. For example, when the driving frequency of the display panel 100 is 90 Hz and the on-duty is 20%, the display panel 100 may display a fixed image during the 20% on-duty and may display the black during 80% off-duty. The user's the visual system may interpolate and perceive the image during the off-duty. Therefore, a perceived driving frequency may be 450 (=90×5) Hz. Here, the perceived driving frequency may be the driving frequency of the display panel 100 perceived by the user. For example, when the driving frequency of the display panel 100 is 60 Hz and the on-duty is 50%, the perceived driving frequency may be 120 (=60×2) Hz. For example, when the driving frequency of the display panel 100 is 120 Hz and the on-duty is 50%, the perceived driving frequency may be 240 (=120×2) Hz. The perceived driving frequency may be referred to as CMR (Clear Motion Rate).

As the perceived driving frequency is large, the motion blur may be small. Therefore, the on-duty is small, the motion blur may be small. For example, a motion blur of a normal driving may be greater than a motion blur of 70% on-duty. For example, the motion blur of the 70% on-duty may be greater than a motion blur of 50% on-duty. For example, the motion blur of the 50% on-duty may be greater than a motion blur of 20% on-duty.

When the perceived driving frequency is greater than or equal to a specific value (e.g., 450 Hz), the user may not feel the motion sickness due to the motion blur. In the display device with the very short viewing distance, such as the VR device, the small area and the high PPI are required, and a pitch occupied by the pixel PX is narrow, such that there may be a restriction on the number of transistors constituting the pixel PX and a signal applied to the pixel PX. Therefore, a driving possible frequency of the display panel 100 may be small. For example, the driving possible frequency of the display panel 100 may be 90 Hz. Therefore, in order to prevent or reduce the user feeling the motion sickness due to the motion blur, the driving frequency of the display panel 100 may be set to 90 Hz, and the on-duty may be set to 20%. Accordingly, the perceived frequency may be 450 Hz, and the user may not feel the motion sickness.

FIG. 19 is a graph showing a noise according to an on-duty.

Referring to FIGS. 1 to 19, as the on-duty is small, the motion blur may be small, and thus, the user may not experience the motion sickness due to the motion blur. However, when the on-duty decreases, a length of the light emission period PEM for the light-emitting element LD may shorten. Therefore, a light-receiving time, which is a time during which the light-receiving element PD receives the light from the light-emitting element LD, may shorten. because the light-receiving time shortens, an accuracy of the voltage measurer 300 inevitably decreases due to a noise. For example, a light-receiving time of 100% on-duty may be longer than a light-receiving time of 20% on-duty. Therefore, an accuracy of a time-luminance graph of 100% on-duty may be greater than an accuracy of a time-luminance graph of 20% on-duty. For example, a determination coefficient R2 of the 100% on-duty may be 0.997. For example, the determination coefficient R2 of the 20% on-duty may be 0.454. Here, the determination coefficient represents an accuracy of data and has a value between 0 and 1, and as the determination coefficient is to 1, the accuracy of the data may be large. In order for the lifetime evaluation of the display panel 100 to be reliable, the determination coefficient R2 should be greater than 0.9, for example.

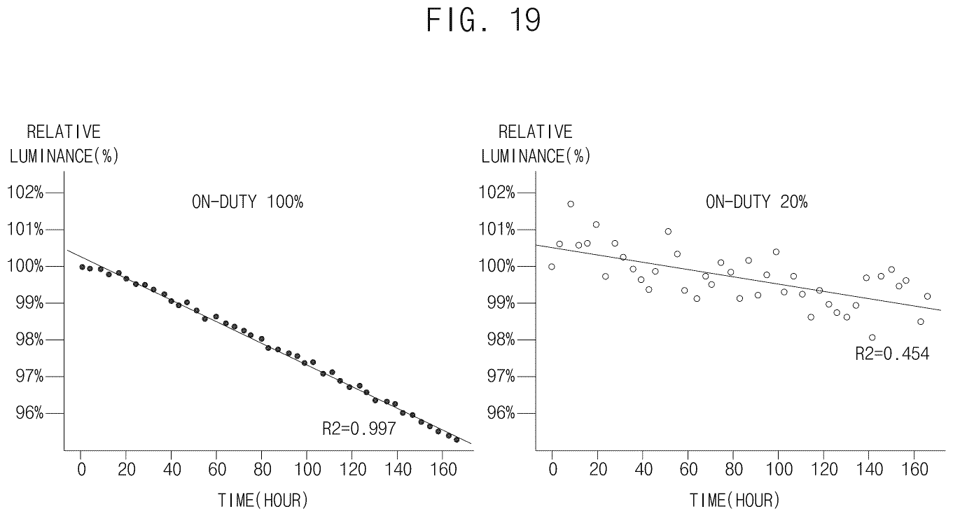

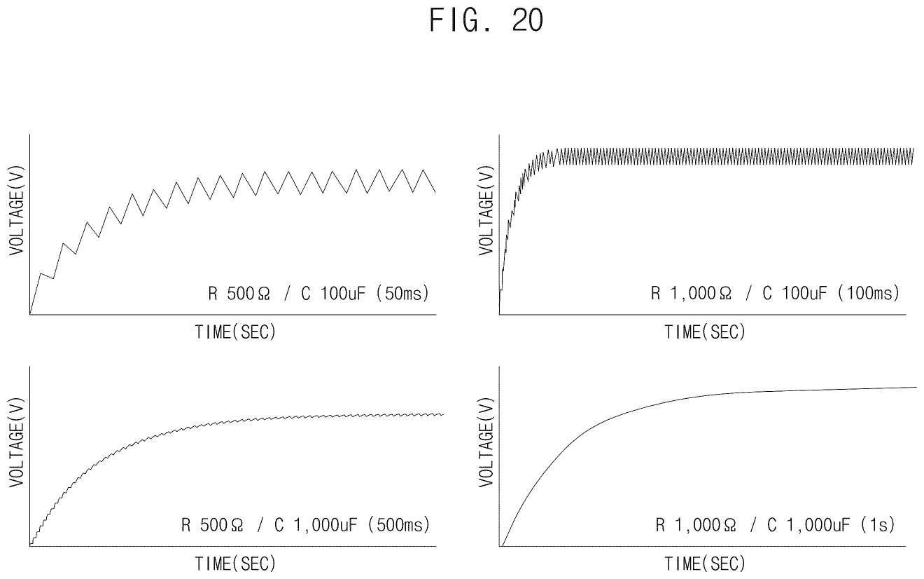

FIG. 20 is a graph showing an example of a method for increasing a reliability of a lifetime evaluation of a lifetime evaluation device of FIG. 8.

Referring to FIGS. 1 to 20, the RC circuit RCC may include the variable light-receiving resistor R and the light-receiving capacitor C, and the resistance value of the variable photodetector R may vary according to the on-duty and the driving frequency of the display panel 100.

As the on-duty is small, the resistance value of the variable light-receiving resistor R may be large.

$$\frac{VOUT ( s )}{IIN ( s )} = \frac{R}{1 + s \times C \times R} \qquad Mathematical Formula 2$$

(a time constant is R×C, and an amplitude is R. The time constant represents the response time of the output voltage VOUT for the input current IIN.)

Specifically, as described above, the RC circuit RCC may operate as the low-pass filter. The low-pass filter may remove a high-frequency component. However, the noise may be included in the high-frequency component a lot, and as the time constant is large, a performance of the low-pass filter may be enhanced, such that the low-pass filter may effectively remove the high-frequency component. As the resistance value of the variable light-receiving resistor R is large, the time constant may be large, and the low-pass filter may effectively remove the noise. For example, when the resistance value of the variable light-receiving resistor R is 500Ω and the capacitance of the light-receiving capacitor C is 100 uF, the time constant may be 50 m second. For example, when the resistance value of the variable light-receiving resistor R is 1000Ω and the capacitance of the light-receiving capacitor C is 100 uF, the time constant may be 100 m second. For example, when the resistance value of the variable light-receiving resistor R is 500Ω and the capacitance of the light-receiving capacitor C is 1000 uF, the time constant may be 500 m second. For example, when the resistance value of the variable light-receiving resistor R is 1000Ω and the capacitance of the light-receiving capacitor C is 1000 uF, the time constant may be 1 second. In summary, as the on-duty is small, the noise may be large. In order to effectively remove the noise, the resistance value of the variable light-receiving resistor R may increase, and the performance of the RC circuit RCC as a low-pass filter may be relatively improved, such that the noise may be effectively removed.

As the driving frequency of the display panel 100 is large, the resistance value of the variable light-receiving resistor R may be large. Specifically, as described above, as the driving frequency of the display panel 100 is large, the length of the frame period FP may be short. Therefore, the light-receiving time may be shortened. Because the light-receiving time is shortened, the noise may be large. Therefore, in order to effectively remove the noise, the resistance value of the variable photodetector R may be increased, and the performance of the RC circuit RCC as the low-pass filter may be relatively improved, so that the noise may be effectively removed.

In addition, in order to effectively remove the noise, a measurement cycle of the output voltage VOUT of the voltage measurer 300 may be changed according to the on-duty and the driving frequency of the display panel 100. Specifically, as the on-duty of the light-emitting element LD is small, the measurement cycle of the output voltage VOUT may be long. Accordingly, the light-receiving time may be sufficiently secured. Furthermore, as the driving frequency of the display panel 100 is large, the measurement cycle of the output voltage VOUT may be long. Accordingly, the light-receiving time may be sufficiently secured.

As such, because the resistance value of the variable light-receiving resistor R included in the RC circuit RCC changes according to the on-duty and the driving frequency of the display panel 100, the performance of the RC circuit RCC as the low-pass filter may be relatively improved, such that the noise may be effectively removed. Accordingly, the reliability of the lifetime evaluation of the display panel 100 may be relatively improved.

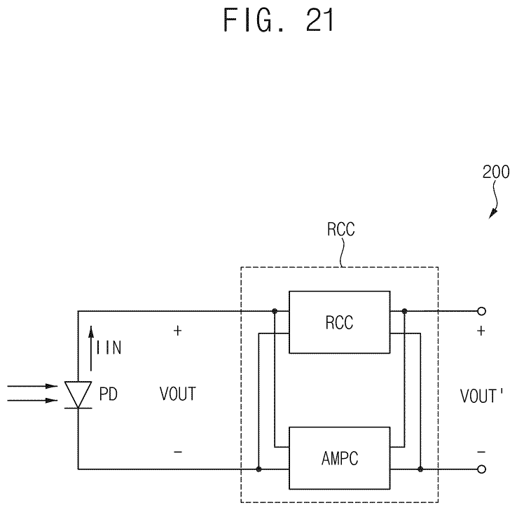

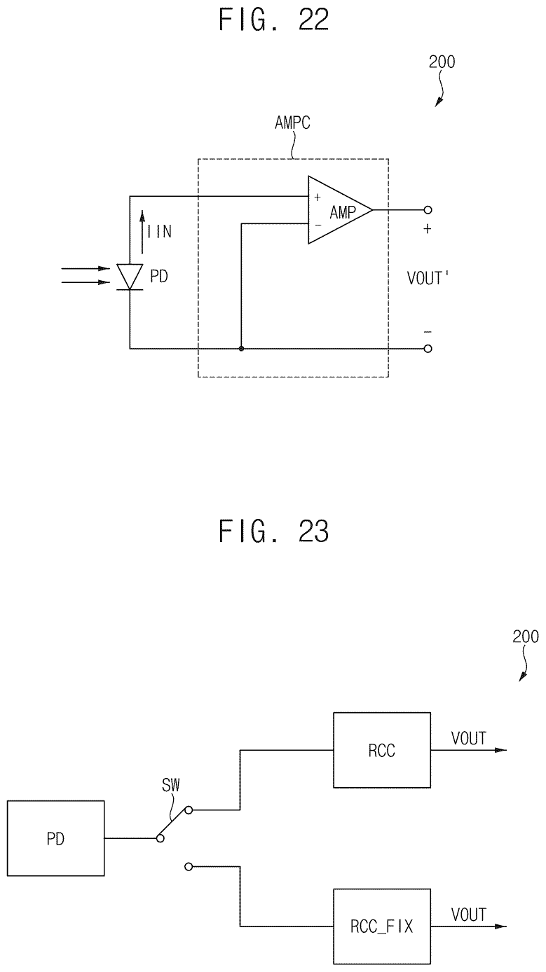

FIG. 21 and FIG. 22 are circuit diagrams showing examples of a method for increasing a reliability of a lifetime evaluation of a lifetime evaluation device of FIG. 8.

Referring to FIGS. 1 to 22, as the on-duty is small or the driving frequency of the display panel 100 is large, the light-receiving time may be short. When the light-receiving time becomes short, the output voltage VOUT may become small. Because the output voltage VOUT becomes small, the accuracy of the voltage measurer 300 may decrease.

In order to prevent or reduce this problem, the voltage outputter 200 may further include a voltage amplification circuit AMPC. The voltage amplification circuit AMPC may be connected in parallel with the RC circuit RCC. The voltage amplification circuit AMPC may include an amplifier AMP. The amplifier AMP may amplify the output voltage VOUT to generate an amplified output voltage VOUT′.

As such, the voltage outputter 200 may further include the amplifier AMP, such that the output voltage VOUT may increase and the accuracy of the voltage measurer 300 may decrease. Accordingly, the reliability of the lifetime evaluation of the display panel 100 may be relatively improved.

FIG. 23 is a block diagram showing an example of a method for increasing a reliability of a lifetime evaluation of a lifetime evaluation device of FIG. 8.

Referring to FIGS. 1 to 23, the voltage outputter 200 may include the RC circuit RCC. The voltage outputter 200 may further include a fixed RC circuit RCC_FIX.

The light-receiving element PD may be selectively connected to the RC circuit RCC or the fixed RC circuit RCC_FIX through a switch SW. The fixed RC circuit RCC_FIX may include a fixed light-receiving resistor and a fixed light-receiving capacitor. The light-receiving element PD may be connected in parallel with the fixed light-receiving resistor and the fixed light-receiving capacitor.

As such, the voltage outputter 200 further includes the fixed RC circuit RCC_FIX, such that the RC circuit RCC or the fixed RC circuit RCC_FIX may be selectively used according to the user's a usage situation.

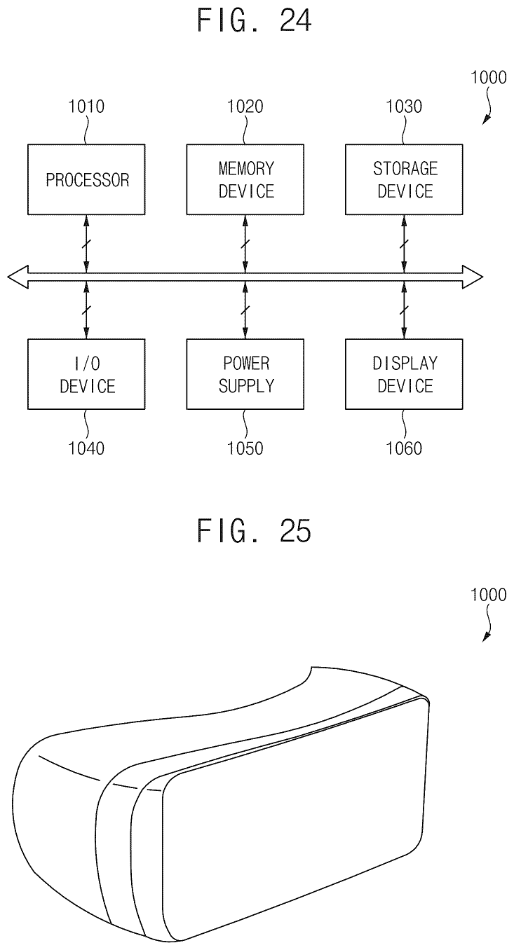

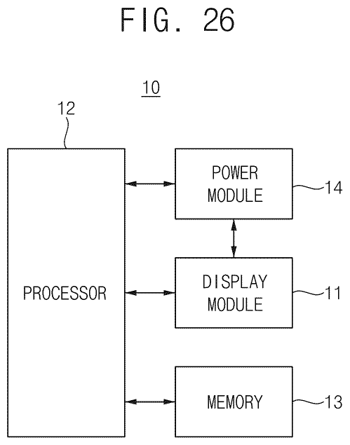

FIG. 24 is a block diagram showing an electronic device 1000 according to some embodiments of the present disclosure. FIG. 25 is a diagram showing an example in which an electronic device 1000 of FIG. 24 is implemented as a VR device.

Referring to FIGS. 1 to 25, the electronic device 1000 may include a processor 1010, a memory device 1020, a storage device 1030, an input/output (I/O) device 1040, a power supply 1050 and a display device 1060. Here, the display device 1060 may be the display device of FIG. 1. In addition, the electronic device 1000 may further include a plurality of ports for communicating with a video card, a sound card, a memory card, a universal serial bus (USB) device, other electronic devices, etc.

According to some embodiments, as shown in FIG. 25, the electronic device 1000 may be implemented as a smart phone. However, the electronic device 1000 is not limited thereto. For example, the electronic device 1000 may be implemented as a cellular phone, a video phone, a smart pad, a smart watch, a tablet PC, a car navigation system, a computer monitor, a laptop, a head mounted display (HMD) device, and the like.

The processor 1010 may perform various computing functions or various tasks. The processor 1010 may be a micro-processor, a central processing unit (CPU), an application processor (AP), and the like. The processor 1010 may be coupled to other components via an address bus, a control bus, a data bus, etc. Further, the processor 1010 may be coupled to an extended bus such as a peripheral component interconnection (PCI) bus.

The processor 1010 may output the input image data IMG and the input control signal CONT to the driving controller 120 of FIG. 1.

The memory device 1020 may store data for operations of the electronic device 1000. For example, the memory device 1020 may include at least one nonvolatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and the like and/or at least one volatile memory device such as a dynamic random access memory (DRAM) device, a static random access memory (SRAM) device, a mobile DRAM device, and the like.

The storage device 1030 may include a solid state drive (SSD) device, a hard disk drive (HDD) device, a CD-ROM device, and the like. The I/O device 1040 may include an input device such as a keyboard, a keypad, a mouse device, a touch-pad, a touch-screen, and the like and an output device such as a printer, a speaker, and the like. In some embodiments, the display device 1060 may be included in the I/O device 1040. The power supply 1050 may provide power for operations of the electronic device 1000. The display device 1060 may be coupled to other components via the buses or other communication links.

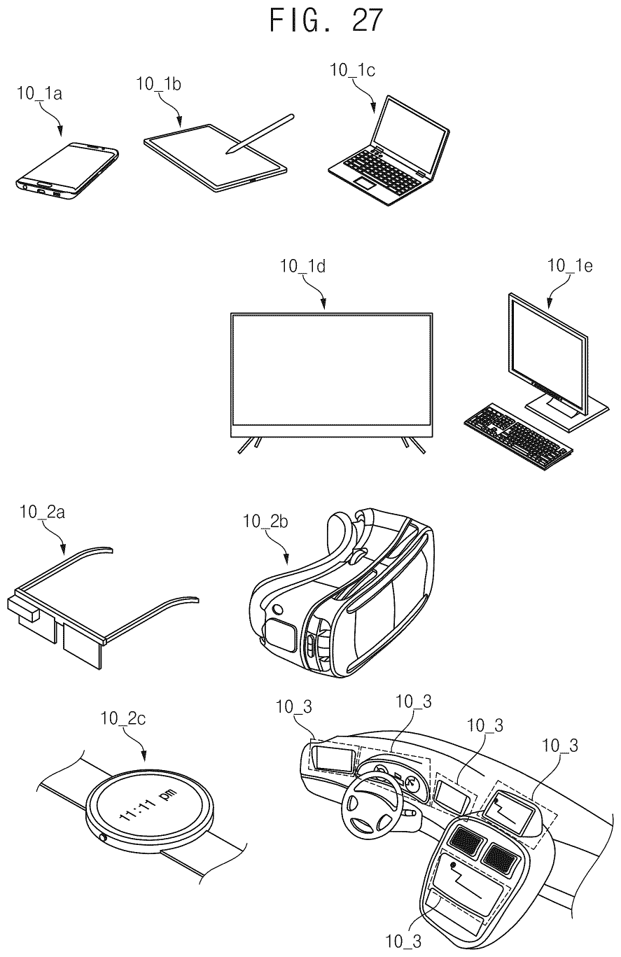

FIG. 26 is a block diagram showing an electronic device 10 according to some embodiments of the present disclosure. FIG. 27 is schematic diagrams showing electronic devices of FIG. 26.

Referring to FIG. 26, the electronic device 10 according to some embodiments may include a display module 11, a processor 12, a memory 13 and a power module 14.

The display device according to some embodiments of the present disclosure may be applied to various electronic devices.

According to some embodiments, the electronic device 10 may include the display device of FIG. 1. An operation of the display device included in the electronic device 10 may be the same as the operation of the display device explained referring to FIGS. 1 to 23. The electronic device 10 may further include a module or an device having additional functions in addition to the display device.

The processor 12 may include at least one of a central processing unit (CPU), an application processor (AP), a graphic processing unit (GPU), a communication processor (CP), an image signal processor (ISP), or a controller.

According to some embodiments, the processor 12 may provide the input control signal CONT of FIG. 1 and the input image data IMG of FIG. 1 to the driving controller 120 included in the display device of FIG. 1.

According to some embodiments, the processor 12 may be divided into two or more in a functional or structural perspective. For example, the processor 12 may include a main processor, which is a first driving chip type, including the central processing unit and an auxiliary processor, which is a second driving chip type, including a controller receiving an image signal from the main processor and processing the image signal to match interface specifications of the display module 11. For example, the auxiliary processor may include the driving controller 120 included in the display device of FIG. 1. Thus, the main processor may provide the input control signal CONT of the FIG. 1 and the input image data IMG of FIG. 1 to the auxiliary processor. The auxiliary processor may process the image signal based on the input control signal CONT and the input image data IMG.

The memory 13 may include at least one of a nonvolatile memory or a volatile memory. Data information required for the operation of the processor 12 or the display module 11 may be stored in the memory 13. When the processor 12 executes an application stored in the memory 13, the input control signal CONT and/or the input image data IMG may be transmitted to the display module 11 and the display module 11 may process the input control signal CONT and/or the input image data IMG and may output image information through a display area.

The power module 14 may include a power supply module, such as a power adapter or a battery device, and a power conversion module converting power supplied by the power supply module to generate a power required for the operation of the electronic device 10.

At least one of the elements of the electronic device 10 may be included in the display device according to some embodiments of the present disclosure. In addition, a part of a single functional module may be included in the display device and another part of the single functional module may be located out of the display device. For example, the display module 11 may be included in the display device but the processor 12, the memory 13 and the power module 14 may be included in another device in the electronic device 10 which is not the display device.

Referring to FIG. 27, the various electronic devices including the display device according to the present embodiments may include electronic devices for displaying image such as a smartphone 10_1a, a tablet PC 10_1b, a laptop 10_1c, a television 10_1d, a desktop monitor 10_1e, wearable electronic devices including a display module such as smart glasses 10_2a, a head mounted display 10_2b and a smart watch 10_2c and vehicle electronic devices 10_3 including display modules such as a CID (center information display), a room mirror display located on an instrument panel, center fascia, and a dashboard of a vehicle. The electronic device 10 may not be limited to the electronic devices for displaying image, the wearable electronic devices and the vehicle electronic devices 10_3.

According to the driver, the display device including the driver and the electronic device including the driver of the present embodiments as explained above, the power consumption of the display device may be relatively reduced.

The foregoing is illustrative of aspects of some embodiments of the present disclosure and is not to be construed as limiting thereof. Although aspects of some embodiments of the present disclosure have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of the present disclosure and is not to be construed as limited to the specific example embodiments disclosed, and that modifications to the disclosed example embodiments, as well as other example embodiments, are intended to be included within the scope of the appended claims, and their equivalents. The present disclosure is defined by the following claims, with equivalents of the claims to be included therein.

What is claimed is:

1. A lifetime evaluation device of a display panel comprising:
a display panel including a light-emitting element;
a voltage outputter including a light-receiving element configured to receive a luminance of the light-emitting element and to generate an input current, and an RC circuit connected to the light-receiving element and configured to generate an output voltage;
a voltage measurer configured to measure the output voltage; and
a lifetime evaluation controller configured to evaluate a lifespan of the display panel based on the output voltage,
wherein the RC circuit includes a variable light-receiving resistor and a light-receiving capacitor, and a resistance value of the variable light-receiving resistor is configured to change according to an on-duty of the light-emitting element.

2. The lifetime evaluation device of claim 1, wherein the lifetime evaluation controller is configured to calculate the luminance of the light-emitting element based on the output voltage, and
wherein, based on the luminance of the light-emitting element being less than a luminance threshold value, the lifetime evaluation controller is configured to evaluate the lifetime of the display panel is ended.

3. The lifetime evaluation device of claim 1, wherein, as the on-duty of the light-emitting element is small, the resistance value of the variable light-receiving resistor is large.

4. The lifetime evaluation device of claim 1, wherein the resistance value of the variable light-receiving resistor is configured to change according to a driving frequency of the display panel.

5. The lifetime evaluation device of claim 4, wherein, as the driving frequency of the display panel is large, the resistance value of the variable light-receiving resistor is large.

6. The lifetime evaluation device of claim 1, wherein the voltage outputter further includes an amplifier configured to amplify the output voltage.

7. The lifetime evaluation device of claim 1, wherein a measurement cycle of the output voltage changes according to the on-duty of the light-emitting element.

8. The lifetime evaluation device of claim 7, wherein, as the on-duty of the light-emitting element is small, the measurement cycle of the output voltage is long.

9. The lifetime evaluation device of claim 7, wherein the measurement cycle of the output voltage is configured to change according to a driving frequency of the display panel.

10. The lifetime evaluation device of claim 9, wherein, as the driving frequency of the display panel is large, the measurement cycle of the output voltage is long.

11. The lifetime evaluation device of claim 1, wherein the voltage measurer further includes a fixed RC circuit including a fixed light-receiving resistor and a fixed light-receiving capacitor, and
wherein the RC circuit and the fixed RC circuit are selectively connected to the light-emitting element.

12. The lifetime evaluation device of claim 1, wherein the display panel includes at least two display panels, and the lifetime evaluation controller is configured to evaluate a lifetime of each of the display panels.

13. A lifetime evaluation method of a display panel comprising:
receiving a luminance of a light-emitting element included in a display panel to generate an input current using a voltage outputter;
generating an output voltage based on the input current using an RC circuit included in the voltage outputter;
measuring the output voltage; and
evaluating a lifetime of the display panel based on the output voltage,
wherein the RC circuit includes a variable light-receiving resistor and a light-receiving capacitor, and a resistance value of the variable light-receiving resistor changes according to an on-duty of the light-emitting element.

14. The lifetime evaluation method of claim 13, wherein the luminance of the light-emitting element is calculated based on the output voltage, and
wherein, when the luminance of the light-emitting element is less than a luminance threshold value, the lifetime evaluation controller is configured to evaluate the lifetime of the display panel is ended.

15. The lifetime evaluation method of claim 13, wherein, as the on-duty of the light-emitting element is small, the resistance value of the variable light-receiving resistor is large.

16. The lifetime evaluation method of claim 13, wherein the resistance value of the variable light-receiving resistor changes according to a driving frequency of the display panel.

17. The lifetime evaluation method of claim 16, wherein, as the driving frequency of the display panel is large, the resistance value of the variable light-receiving resistor is large.

18. The lifetime evaluation method of claim 13, wherein the voltage outputter further includes an amplifier configured to amplify the output voltage.

19. The lifetime evaluation method of claim 13, wherein a measurement cycle of the output voltage changes according to the on-duty of the light-emitting element.

20. The lifetime evaluation method of claim 19, wherein, as the on-duty of the light-emitting element is small, the measurement cycle of the output voltage is long.
